(19) United States
(12) Patent Application Publication
(10) Pub. No.: US 2023/0009859 A1
(43) Pub. Date: Jan. 12, 2023

(54) ASYMMETRIC PURGED BLOCK BENEATH WAFER PLANE TO MANAGE NON-UNIFORMITY

(71) Applicant: LAM RESEARCH CORPORATION, Fremont, CA (US)

(72) Inventors: Ramesh CHANDRASEKHARAN, Lake Oswego, OR (US); Adrien LAVOIE, Newberg, OR (US); Michael Philip ROBERTS, Tigard, OR (US)

(21) Appl. No.: 17/784,751

(22) PCT Filed: Dec. 15, 2020
(86) PCT No.: PCT/US2020/065115

§ 371 Date: Jun. 13, 2022

Related U.S. Application Data
(60) Provisional application No. 62/949,825, filed on Dec. 18, 2019.

(51) Int. Cl. H01J 37/32; C23C 16/44; C23C 16/458

(52) U.S. Cl. CPC H01J 37/32449; H01J 37/32834; C23C 16/4408; C23C 16/4585; C23C 16/4412

(57) ABSTRACT

A purge baffle for a substrate support includes an annular ring configured to surround an outer perimeter around the substrate support in a volume below the substrate support and a first portion. The first portion includes a plenum defined below the first portion and outside of the annular ring in the volume below the substrate support and a plurality of openings that provide respective flow paths from a region above the first portion into the plenum. At least a first opening of the plurality of openings has a first conductance and at least a second opening of the plurality of openings has a second conductance that is different than the first conductance.

### CROSS-REFERENCE TO RELATED APPLICATIONS

This application claims the benefit of U.S. Provisional Application No. 62/949,825, filed on Dec. 18, 2019. The present disclosure is related by subject matter to U.S. patent application Ser. No. 14/872,513 (now U.S. Pat. No. 10,157,755), filed on Oct. 15, 2018, and U.S. patent application Ser. No. 16/220,914, filed on Dec. 14, 2018. The entire disclosures of the applications referenced above are incorporated herein by reference.

### FIELD

The present disclosure relates to purging gas mixtures from a processing chamber in a substrate processing system.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Examples of substrate treatments include etching, deposition, photoresist removal, etc. During processing, the substrate is arranged on a substrate support and one or more process gases may be introduced into the processing chamber. For example, the substrate support is a pedestal, electrostatic chuck, and/or other structure defining a surface configured to support the substrate during processing. The one or more process gases may be delivered by a gas delivery system to the processing chamber using a gas distribution device such as a showerhead.

During processing, different gas mixtures may be introduced into the processing chamber and then evacuated. The process is repeated multiple times to deposit film, to etch the substrate and/or to perform other substrate treatments. In some substrate processing systems, radio frequency (RF) plasma may be used to activate chemical reactions. In some examples, the process deposits a thin film on a substrate using atomic layer deposition (ALD).

### SUMMARY

A purge baffle for a substrate support includes an annular ring configured to surround an outer perimeter around the substrate support in a volume below the substrate support and a first portion. The first portion comprises a plenum defined below the first portion and outside of the annular ring in the volume below the substrate support and a plurality of openings that provide respective flow paths from a region above the first portion into the plenum. At least a first opening of the plurality of openings has a first conductance and at least a second opening of the plurality of openings has a second conductance that is different than the first conductance.

In other features, the first opening and the second opening have different lengths. The first opening and the second opening have different diameters. The plurality of openings correspond to a plurality of holes. The plurality of openings correspond to a plurality of slits. The first portion has an asymmetrical shape. The first portion has an elliptical shape. Respective conductances of the plurality of openings vary in accordance with a distance from a port of a processing chamber.

In other features, a lower surface of the first portion is stepped. The lower surface includes a first step and a second step that has a different height than the first step, the first opening is arranged in the first step, and the second opening is arranged in the second step. A lower surface of the first portion is sloped. A processing chamber includes the purge baffle and the substrate support and the purge baffle is arranged in the volume below the substrate support. An inner diameter of the annular ring is 1-2 mm greater than an outer diameter of the substrate support. The volume below the substrate support is asymmetrical.

A purge baffle for a substrate support in a processing chamber includes a shroud configured to define an annular plenum in a volume below the substrate support, a plurality of openings in the shroud providing respective flow paths from a region above the substrate support into the plenum, and a plurality of passages defined within the plenum that correspond to respective ones of the plurality of openings. Each of the plurality of passages is configured to provide a same flow rate of gases from a region above the substrate support to a port of the processing chamber.

In other features, the plurality of passages includes a first passage that corresponds to a first opening of the plurality of openings and a second passage that corresponds to a second opening of the plurality of openings, wherein the first opening is a first distance from the port and the second opening is a second distance from the port that is different than the first distance. A system includes the processing chamber, the substrate support, and the purge baffle and the purge baffle is arranged in the volume below the substrate support. An inner diameter of the shroud is 1-2 mm greater than an outer diameter of the substrate support. The volume is asymmetrical and the shroud is generally circular. The volume is elliptical and the shroud is generally circular.

A purge baffle for a substrate support includes a ring including a body defining a central opening. The ring is configured to surround the substrate support. The ring includes an upper portion defining a plenum below the upper portion in a volume below the substrate support and a plurality of openings disposed in the upper portion. The plurality of openings provides respective flow paths from a region above the upper portion into the plenum. A first opening of the plurality of openings has a first conductance. A second opening of the plurality of openings has a second conductance that is different than the first conductance. The first opening and the second opening have at least one of different lengths and different diameters.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system according to the present disclosure;

FIG. 2 shows an example purge baffle according to the present disclosure;

FIG. 3A is a cross-sectional view of another example purge baffle according to the present disclosure;

FIG. 3B is another cross-sectional view of the example purge baffle of FIG. 3A;

FIG. 3C is a top view of the example purge baffle according to the present disclosure;

FIG. 3D is a bottom view of the example purge baffle according to the present disclosure; and

FIG. 3E shows a stepped lower surface of the purge baffle according to the present disclosure.

In the drawings, reference numbers may be reused to identify similar and/or identical elements.

### DETAILED DESCRIPTION

Some substrate processing systems implement a reaction zone between the substrate and the gas distribution device (e.g., a showerhead). The reaction zone may be isolated from a large processing chamber volume using a gas curtain. The large processing chamber volume can help to mitigate parasitic coupling to grounded processing chamber walls (e.g., due to the increased distance from the reaction zone to the processing chamber walls). However, the large processing chamber volume may include dead volumes that impede uniformity of flow and cause particles to accumulate, which may increase defects. For example, dead volumes may appear above a horizontal plane of the showerhead. As another example, dead volumes may appear below a horizontal plane of the substrate support (e.g., in a “pedestal well” below the substrate support).

In some examples, the pedestal well has a non-symmetrical (e.g., elliptical or prolate spheroid) shape and flow paths below the substrate support may not be uniform. For example, the flow paths may not be azimuthally uniform. In other words, the flow paths at various azimuthal locations around the pedestal well may have different lengths and/or pressure differentials. Accordingly, the dead zone in the pedestal well may not be actively purged.

In other examples, temperatures of surfaces below the substrate support may be different than temperatures of surfaces above the substrate support. For example, temperatures of the surfaces below the substrate support may be less than temperatures of surfaces above the substrate support. Accordingly, precursor adsorption and reaction with oxidizing or clean gas radicals with long mean free paths below the substrate support may increase. Accordingly, residue buildup (e.g., parasitic oxide or chlorofluoride type (CFₓ) formation) may occur. These residues are typically non-volatile but can affect on-wafer performance over time.

Systems and methods according to the principles of the present disclosure implement a purge or pumping baffle configured to provide asymmetric purge flow paths below the substrate support. For example, the purge baffle may correspond to a generally hollow structure defining the asymmetric flow paths or a solid block having the asymmetric flow paths defined therein. The asymmetric flow paths are isolated from one another. Further, the asymmetric flow paths equalize azimuthal flow from below the substrate support to a foreline of the substrate processing system. In this manner, respective flows of each of the flow paths are configured to pump gases from the processing chamber (e.g., from a plane corresponding to a surface of the substrate) at a same rate.

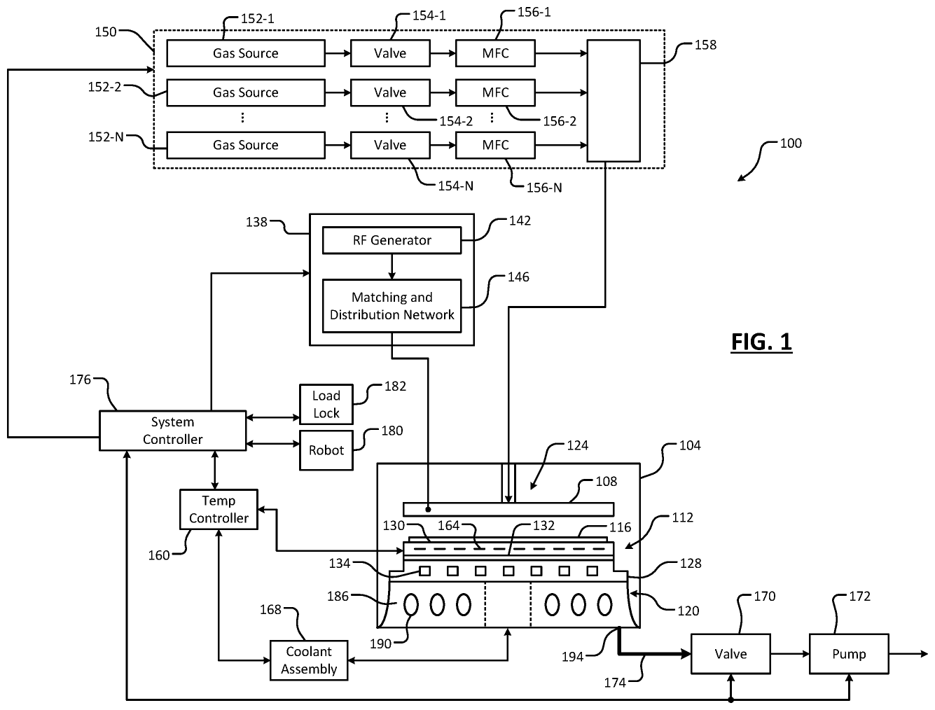

Referring now to FIG. 1, an example substrate processing system 100 is shown. While the foregoing example will be described in the context of atomic layer deposition (ALD), the present disclosure may be applied to other substrate processing systems configured to perform processes including, but not limited to, plasma enhanced ALD (PEALD), thermal ALD, chemical vapor deposition (CVD), plasma enhanced CVD (PECVD), atomic layer etching (ALE), and plasma enhanced ALE (PEALE). The substrate processing system 100 includes a processing chamber 104 that encloses other components of the substrate processing system 100 and contains RF plasma (if used). The processing chamber 104 includes a top surface, a bottom surface, and side surfaces.

The substrate processing system 100 includes an upper electrode 108 and a substrate support 112. In some examples, the substrate support 112 includes an electrostatic chuck. During operation, a substrate 116 is arranged on the substrate support 112. A volume (e.g., a pedestal well 120) is defined between the substrate support and a bottom surface of the processing chamber 104.

For example only, the upper electrode 108 may include a gas distribution device 124 such as a showerhead that introduces and distributes process gases. A substrate-facing surface or faceplate of the base portion of the showerhead includes a plurality of holes through which process gas or purge gas flows. Alternately, the upper electrode 108 may include a conducting plate. In examples where the upper electrode 108 includes the conducting plate, the process gases may be introduced in another manner.

In some examples, the substrate support 112 may include a lower electrode 128. The lower electrode 128 may support a heating plate 130. The heating plate 130 may correspond to a ceramic multi-zone heating plate. A thermal resistance layer 132 may be arranged between the heating plate 130 and the lower electrode 128. The lower electrode 128 may include one or more coolant channels 134 for flowing coolant through the lower electrode 128.

An RF generating system 138 generates and outputs an RF voltage to one of the upper electrode 108 and the lower electrode 128. The other one of the upper electrode 108 and the lower electrode 128 may be DC grounded, AC grounded or floating. For example only, the RF generating system 138 may include an RF generator 142 that generates RF power that is fed by a matching and distribution network 146 to the upper electrode 108 or the lower electrode 128. In other examples, the plasma may be generated inductively or remotely.

A gas delivery system 150 includes one or more gas sources 152-1, 152-2, . . . , and 152-N (referred to collectively as gas sources 152), where N is an integer greater than zero. The gas sources 152 are connected by valves 154-1, 154-2, . . . , and 154-N (referred to collectively as valves 154) and mass flow controllers 156-1, 156-2, . . . , and 156-N (referred to collectively as mass flow controllers 156) to a manifold 158.

A temperature controller 160 may be connected to a plurality of thermal control elements (TCEs) 164 arranged in the heating plate 130. The temperature controller 160 may be used to control the plurality of TCEs 164 to control a temperature of the substrate support 112 and the substrate 116. The temperature controller 160 may communicate with a coolant assembly 168 to control coolant flow through the channels 134. For example, the coolant assembly 168 may include a coolant pump and reservoir. The temperature controller 160 operates the coolant assembly 168 to selectively flow the coolant through the channels 134 to cool the substrate support 112.

A valve 170 and pump 172 may be used to evacuate reactants (e.g., process gases and materials) and purge gases from the processing chamber 104. For example, the valve 170 and pump 172 draw gases out of the processing chamber 104 through a foreline 174 of the substrate processing system 100. A system controller 176 may be used to control components of the substrate processing system 100. A robot 180 may be used to deliver substrates onto, and remove substrates from, the substrate support 112. For example, the robot 180 may transfer substrates between the substrate support 112 and a load lock 182.

The processing chamber 104 according to the present disclosure includes a purge baffle 186 configured to define a plenum (e.g., a defined space or volume) therein to provide asymmetric purge flow paths below the substrate support 112 as described below in more detail. For example, purge gases are supplied into the flow paths defined within the purge baffle 186 via respective openings 190. The purge gases flow out of the processing chamber 104 through a port 194 and into the foreline 174.

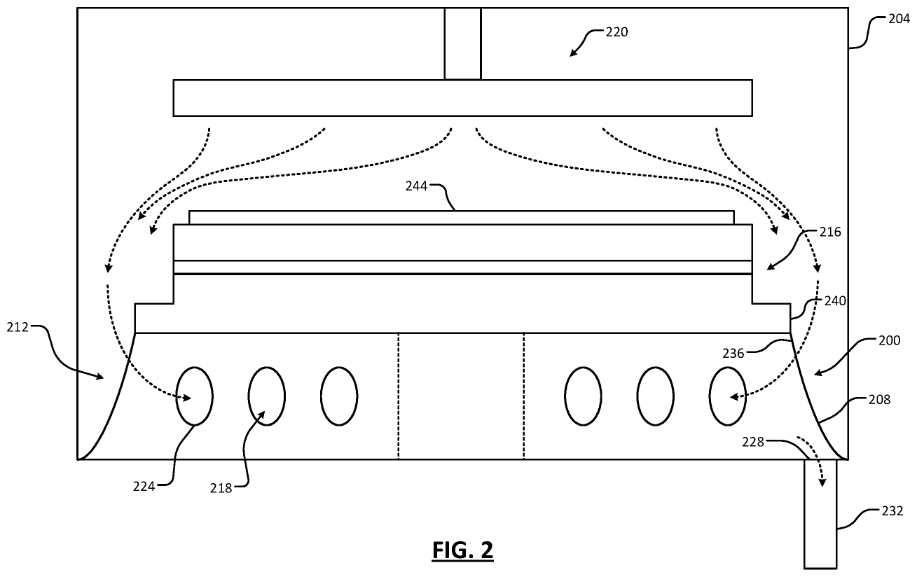

FIG. 2 shows an example purge baffle 200 according to the present disclosure arranged in a processing chamber 204. In this example, the purge baffle 200 includes a shroud 208 arranged in a volume 212 below a substrate support 216. The volume 212 below the substrate support 216 corresponds to a region of the processing chamber 204 defined below (i.e., underneath) the substrate support 216. In other words, the volume 212 is defined between the substrate support 216 and a bottom surface or wall of the processing chamber 204. A plenum defined 218 within the purge baffle 200 includes a plurality of asymmetric purge flow paths. For example, gases supplied by a showerhead 220 flow into the flow paths defined within the purge baffle 200 via respective openings 224. The gases flow out of the processing chamber 204 through a port 228 and into a foreline 232.

For example only, while the volume 212 may be asymmetrical (e.g., elliptical or prolate spheroid shaped in a top-down view), the purge baffle 200 may have a generally symmetrical shape. For example, the purge baffle 200 may have a generally circular or annular shape. An inner diameter 236 of a first portion of the shroud 208 may be slightly (e.g., 1-2 mm) greater than an outer diameter 240 of the substrate support 216. For example, the first portion of the shroud 208 corresponds to an upper portion of the shroud 208 adjacent to and/or in contact with the outer diameter 240 of the substrate support 216. Accordingly, the shroud 208 is configured to be inserted downward over the substrate support 216 for installation within the volume 212.

Each of the openings 224 is a different distance from the port 228. Accordingly, flow paths corresponding to respective ones of the openings 224 may have different lengths corresponding to the different distances between the openings 224 and the port 228. In other words, gases flowing through openings 224 further from the port 228 have flow paths having greater lengths than gases flowing through openings 224 closer to the port 228. Flow paths having different lengths may correspond to different pressure drops and different flow rates (i.e., from a region above the substrate support 216 into the plenum 218 and through the port 228). The different pressure drops and flow rates result in different radial flow velocities above a substrate 244 arranged on the substrate support 216. For example, the flow paths may have azimuthally asymmetric flow rates. The asymmetric flow rates and associated flow velocities may cause process non-uniformities. Accordingly, the purge baffle 200 of the present disclosure is configured symmetric flow rates through openings 224.

For example, flow paths corresponding the openings 224 may be respectively configured to provide a same flow rate of gas molecules regardless of respective positions of the openings 224 relative to the port 228. In one example, the purge baffle 200 may define respective passages within the plenum 218 (e.g., using baffles, fins, piping or tubing, etc.) for each of the openings 224 such that each of the passages has a same overall length from the corresponding opening 224 to the port 228. For example, passages for openings 224 furthest from the port 228 may provide a direct path to the port 228. Conversely, passages for openings 224 closest to the port 228 may provide an indirect (e.g., serpentine, labyrinthine, circuitous, etc.) path to the port 228. In other examples, widths, diameters, etc. of the passages may be varied for respective ones of the openings 224.

Accordingly, configurations of the passages corresponding to the openings 224 may be different to compensate for different flow rates associated with respective positions and distances of the openings 224 from the port 228. In this manner, the purge baffle 200 reduces (i.e., tune outs) flow rate non-uniformities to pump gases from the processing chamber 204 through the openings 224 at a same rate.

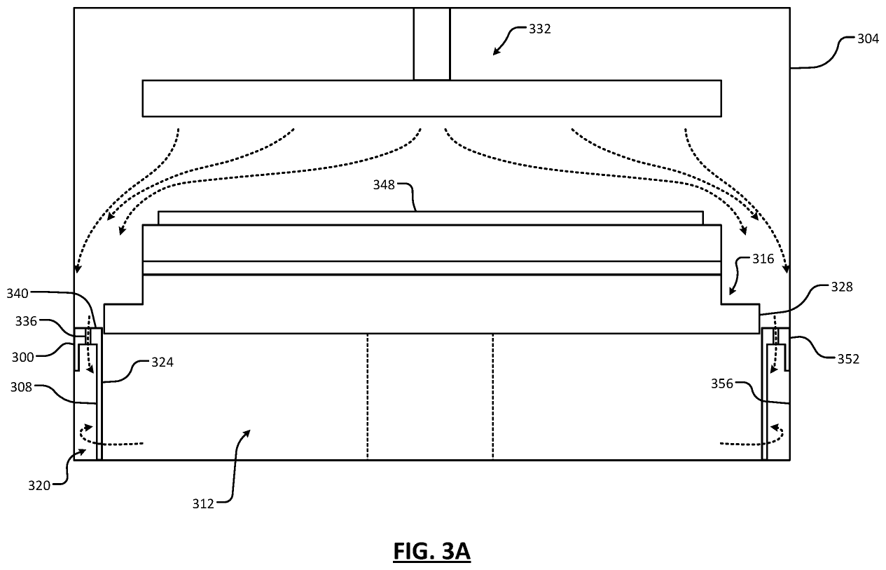

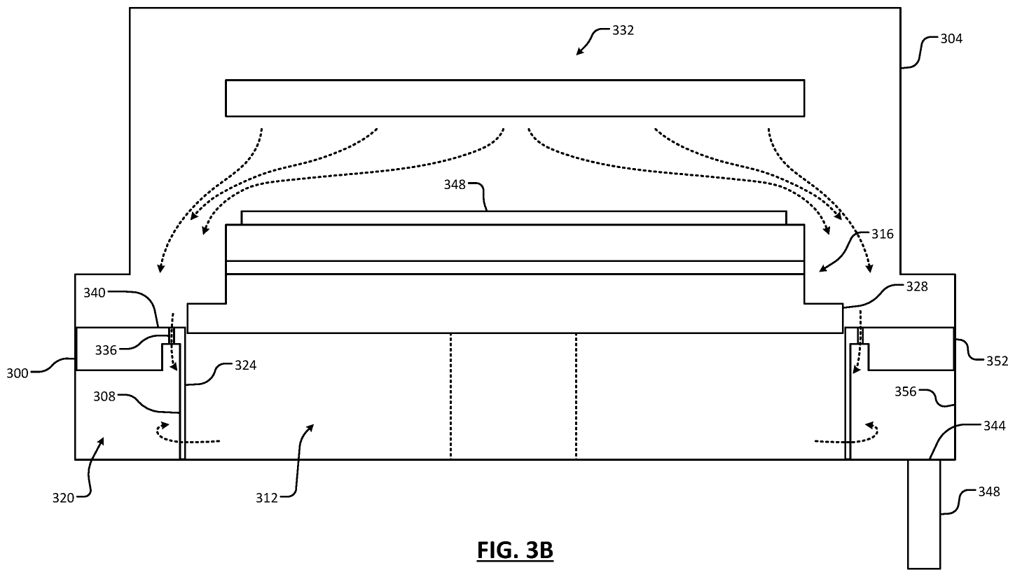

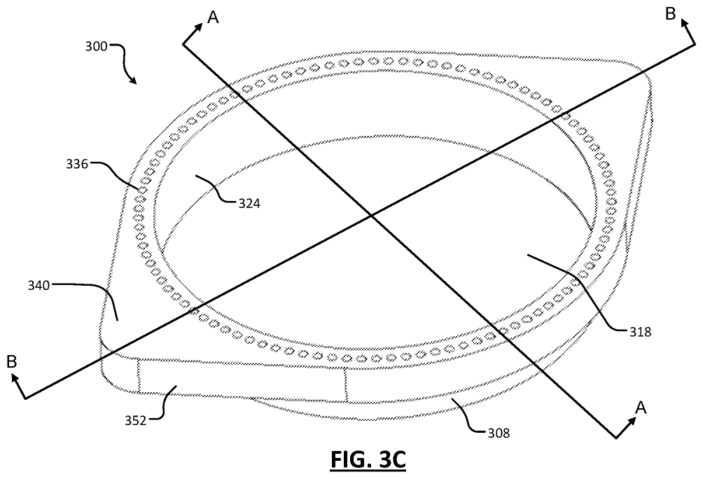

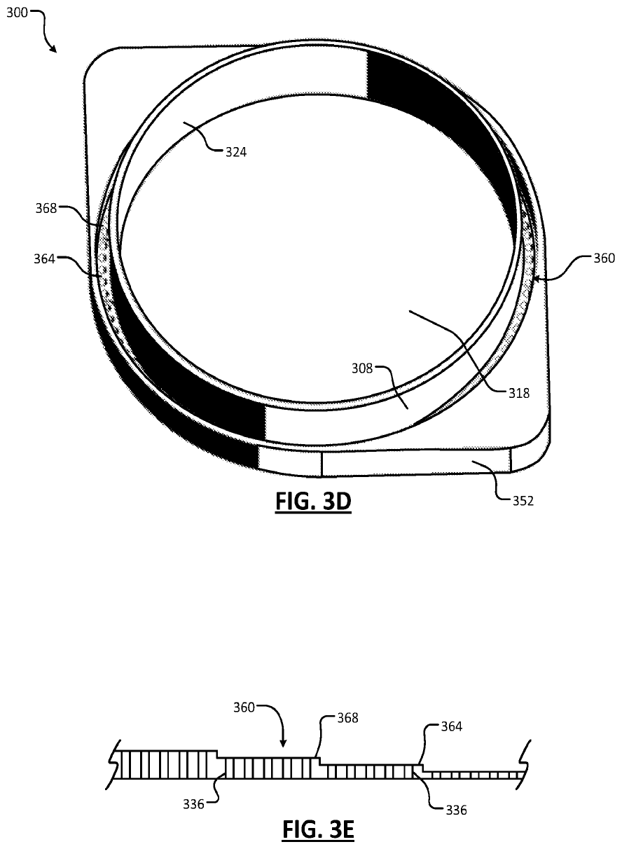

FIGS. 3A, 3B, 3C, 3D, and 3E show another example purge baffle 300 according to the present disclosure arranged in a processing chamber 304. FIG. 3A is a cross-sectional view of the purge baffle 300 taken at line A-A of FIG. 3C. FIG. 3B is a cross-sectional view of the purge baffle 300 taken at line B-B of FIG. 3C. FIG. 3C shows a top view of the purge baffle 300 while FIG. 3D shows a bottom view of the purge baffle 300.

In this example, the purge baffle 300 includes an annular ring 308 arranged in a volume 312 below a substrate support 316. For example, the annular ring 308 includes a circular or ovate body defining a central opening 318. The purge baffle 300 defines an annular plenum 320 below and around an outer perimeter of the substrate support 316. For example, an inner diameter 324 of the annular ring 308 is slightly (e.g., 1-2 mm) greater than an outer diameter 328 of the substrate support 316. Accordingly, the purge baffle 300 is configured to be inserted downward over the substrate support 316 for installation within the volume 312.

Gases supplied by a showerhead 332 flow into holes or openings 336 in an upper portion 340 of the purge baffle 300, into the plenum 320, and out of the processing chamber 304 through a port 344 and into a foreline 348. For example only, the volume 312 may be asymmetrical (e.g., elliptical or prolate spheroid shaped in a top-down view). Similarly, the upper portion 340 of the purge baffle 300 may have an asymmetrical shape corresponding to the shape of the volume 312. Conversely, a lower portion of the purge baffle 300 corresponding to the annular ring 308 is circular or cylindrical, providing a generally symmetrical, annular flow path through the plenum 320.

An outer perimeter 352 of the upper portion 340 is slightly (e.g., 1-2 mm) smaller than an inner surface 356 of the processing chamber 304. Accordingly, an interface between the outer perimeter 352 of the upper portion 340 and the inner surface 352 of the processing chamber 304 prevents leaking between a region above the substrate support 316 and the plenum 320. In some examples, a seal (not shown) may be arranged between the outer perimeter 352 of the upper portion 340 and the inner surface 352 of the processing chamber 304.

Flow paths corresponding to respective ones of the openings 336 have different lengths corresponding to different distances between the openings 336 and the port 344. In other words, gases flowing through openings 336 further from the port 344 have flow paths having greater lengths than gases flowing through openings 336 closer to the port 344. Flow paths having different lengths may correspond to different pressure drops and different flow rates (i.e., from a region above the substrate support 316 into the plenum 320 and through the port 344). The different pressure drops and flow rates result in different radial flow velocities above a substrate 348 arranged on the substrate support 316. For example, the flow paths may have azimuthally asymmetric flow rates. The asymmetric flow rates and associated flow velocities may cause process non-uniformities. Accordingly, the purge baffle 300 of the present disclosure is configured to provide variable conductance (i.e., flow or fluid conductance corresponding to a flow rate of gas molecules).

For example, the openings 336 may be respectively configured to provide a same flow rate of gas molecules regardless of respective positions of the openings 336. In other words, conductances of the openings 336 may be different to compensate for different flow rates associated with respective positions and distances of the openings 336 from the port 344. In the examples shown in FIGS. 3C and 3D, lengths of the openings 336 may vary in accordance with distance from the port 344 to vary the respective conductances of the openings 336. For example, shorter lengths of the openings 336 correspond to greater conductance. Conversely, greater lengths correspond to lower conductance. The variable conductance provided by the purge baffle 300 reduces (i.e., tune outs) flow rate non-uniformities to pump gases from the processing chamber 304 through the openings 336 at a same rate.

As shown in FIGS. 3D and 3E, lengths of the openings 336 are varied by providing a stepped lower surface 360 within the plenum 320. The stepped lower surface 360 provides different heights for the openings 336. Correspondingly, the stepped lower surface 360 provides different lengths for the openings 336. For example, one or more of the openings 336 may be arranged in a first step 364 having a first height. Conversely, one or more others of the openings 336 are arranged in a second step 368 having a second height different from the first height. In this manner, lengths of the openings 336 are varied to provide different conductances. Although the purge baffle 300 is shown with the stepped lower surface 360, in other examples an upper surface of the purge baffle 300 may be stepped instead of or in addition to the lower surface 360. In other examples, the lower surface 360 and/or the upper surface may be sloped or contoured instead of stepped to provide different lengths of the openings 336.

As shown in FIGS. 3A-3E, diameters of the openings 336 may be the same to facilitate machining of the openings 336. In other examples, diameters of the openings 336 may be varied to correspondingly vary the respective conductances of the openings 336. Further, although the openings 336 are shown as generally circular holes, in other examples the openings 336 may correspond to one or more annular slits. In these examples, the conductance may be varied by varying a width of the slits, lengths of the slits, etc. In some examples, the purge baffle 300 may be heated to reduce deposition on surfaces of the purge baffle 300 and the substrate support 316.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A purge baffle for a substrate support, the purge baffle comprising:
an annular ring configured to surround an outer perimeter around the substrate support in a volume below the substrate support; and
a first portion, wherein the first portion comprises
a plenum defined below the first portion and outside of the annular ring in the volume below the substrate support, and
a plurality of openings that provide respective flow paths from a region above the first portion into the plenum, wherein at least a first opening of the plurality of openings has a first conductance and at least a second opening of the plurality of openings has a second conductance that is different than the first conductance.

2. The purge baffle of claim 1, wherein the first opening and the second opening have different lengths.

3. The purge baffle of claim 1, wherein the first opening and the second opening have different diameters.

4. The purge baffle of claim 1, wherein the plurality of openings correspond to a plurality of holes.

5. The purge baffle of claim 1, wherein the plurality of openings correspond to a plurality of slits.

6. The purge baffle of claim 1, wherein the first portion has an asymmetrical shape. The purge baffle of claim 1, wherein the first portion has an elliptical shape.

8. The purge baffle of claim 1, wherein respective conductances of the plurality of openings vary in accordance with a distance from a port of a processing chamber.

9. The purge baffle of claim 1, wherein a lower surface of the first portion is stepped.

10. The purge baffle of claim 9, wherein the lower surface comprises a first step and a second step that has a different height than the first step, the first opening is arranged in the first step, and the second opening is arranged in the second step.

11. The purge baffle of claim 1, wherein a lower surface of the first portion is sloped.

12. A processing chamber, comprising:
the purge baffle of claim 1; and
the substrate support, wherein the purge baffle is arranged in the volume below the substrate support.

13. The processing chamber of claim 12, wherein an inner diameter of the annular ring is 1-2 mm greater than an outer diameter of the substrate support.

14. The processing chamber of claim 12, wherein the volume below the substrate support is asymmetrical.

15. A purge baffle for a substrate support in a processing chamber, the purge baffle comprising:
a shroud configured to define an annular plenum in a volume below the substrate support;
a plurality of openings in the shroud that provide respective flow paths from a region above the substrate support into the plenum; and
a plurality of passages defined within the plenum that correspond to respective ones of the plurality of openings, wherein each of the plurality of passages is configured to provide a same flow rate of gases from a region above the substrate support to a port of the processing chamber.

16. The purge baffle of claim 15, wherein the plurality of passages comprises a first passage that corresponds to a first opening of the plurality of openings and a second passage that corresponds to a second opening of the plurality of openings, wherein the first opening is a first distance from the port and the second opening is a second distance from the port that is different than the first distance.

17. A system, comprising:
the processing chamber;
the substrate support; and
the purge baffle of claim 15, wherein the purge baffle is arranged in the volume below the substrate support.

18. The system of claim 17, wherein an inner diameter of the shroud is 1-2 mm greater than an outer diameter of the substrate support.

19. The system of claim 17, wherein the volume is asymmetrical and the shroud is generally circular.

20. A purge baffle for a substrate support, the purge baffle comprising:
a ring including a body defining a central opening, wherein the ring is configured to surround the substrate support;
an upper portion defining a plenum below the upper portion in a volume below the substrate support; and
a plurality of openings disposed in the upper portion, wherein the plurality of openings provides respective flow paths from a region above the upper portion into the plenum, wherein
a first opening of the plurality of openings has a first conductance,
a second opening of the plurality of openings has a second conductance that is different than the first conductance, and
the first opening and the second opening have at least one of different lengths and different diameters.
